(19) United States
(12) Patent Application Publication
(10) Pub. No.: US 2006/0128138 A1
(43) Pub. Date: Jun. 15, 2006

(54) Gate structure having diffusion barrier layer

(76) Inventor: Haiwei Xin, Shanghai (CN)

Correspondence Address: ROSENBERG, KLEIN & LEE, SUITE 101, 3458 ELLICOTT CENTER DRIVE, ELLICOTT CITY, MD, 21043, US

(21) Appl. No.: 11/352,270

(22) Filed: Feb. 13, 2006

Related U.S. Application Data
(62) Division of application No. 10/995,289, filed on Nov. 24, 2004.

(51) Int. Cl. H01L 21/4763

(52) U.S. Cl. 438/627

(57) ABSTRACT

The present invention provides a gate structure having a diffusion barrier layer and the process for fabrication thereof. A diffusion barrier layer is formed between the polysilicon layer and the tungsten silicide metal layer by using ion implantation, thereby preventing silicon ion diffusion between the polysilicon layer and the tungsten silicide metal layer from forming in the gate re-oxidation process and preventing the lattice stress produced by stress variation, thereby reducing failure of the gate oxide layer.

### BACKGROUND OF THE INVENTION

1. Field of the Invention

The present invention relates to a gate structure and the process for fabrication thereof, and more particularly, to a gate structure having a diffusion barrier layer and the process for fabrication thereof, thereby preventing silicon ion diffusion between the polysilicon layer and the tungsten silicide layer from the gate re-oxidation process and preventing the lattice stress produced by the stress variation.

2. Description of the Prior Art

As integrated circuit geometries continue to plunge into the deep sub-micron regiom, semiconductor devices need to be formed with increasingly smaller dimensions, and with increasingly more complicated process. For example, thickness of the gate oxide layer in a MOSFET device is reduced from hundreds of angstroms to about forty angstroms. The gate structure is increasingly unable to tolerate micro-defects. Therefore, the thin film process is a very important issue in the integrated circuit process. Reliability is closely associated with the yield of the semiconductor products, and directly influences the cost. Currently many manufacturers pay strict attention to the quality of ultra thin gate structures.

Current MOS devices comprise a silicon oxide layer used as a gate oxide layer and a gate conductive layer composed of a polysilicon layer and a tungsten silicide metal layer, thereby defined by lithography processing. However, this process enables the gate oxide layer to be expose in the etching environment, such as plasma, resulting in damage to the quality of the oxide layer, thereby influencing the hot carrier reliability of MOS devices. In order to repair such damage, a gate re-oxidation recipe is performed in the process.

However, in this gate re-oxidation recipe, the original chemical potential energy and thin film stress having the difference between the tungsten silicide metal layer and the polysilicon layer are induced to occur in silicon atom diffusion, thereby causing the production of vacancy and a deformed structure, resulting in the failure of the gate oxide layer.

In the view of this, the present invention provides a gate structure having a diffusion barrier layer in order to overcome the above-mentioned disadvantages.

### SUMMARY OF THE INVENTION

The present invention provides a gate structure having a diffusion barrier layer and the process for fabrication thereof, which prevents the silicon atom diffusion phenomenon between the polysilicon layer and the tungsten silicide layer from the chemical potential energy.

The present invention also provides a gate structure having a diffusion barrier layer and the process for fabrication thereof, which prevents a deformed lattice structure between the polysilicon layer and the tungsten silicide layer by the gate re-oxidation process.

The present invention also provides a gate structure having a diffusion barrier layer and the process for fabrication thereof, which is applied in the deep sub-micron region which is extremely sensitive to the thin film defect, thereby reducing the defect.

The present invention also provides a gate structure having a diffusion barrier layer and the process for fabrication thereof, which alleviates the thin film stress difference between the tungsten silicide metal layer and the polysilicon layer.

According to a preferred embodiment of the present invention, a gate structure having a diffusion barrier layer is provided. A semiconductor substrate is provided. A plurality of isolation structures are formed in the semiconductor substrate. A gate oxide layer is formed on the semiconductor substrate. A polysilicon layer is formed on the gate oxide layer. A tungsten silicide metal layer is formed on the surface of the polysilicon layer. An ion implantation is performed on the semiconductor substrate by using silicon ions, resulting in forming a diffusion barrier layer between the polysilion layer and the tungsten silicide metal layer.

According to another embodiment of the present invention, a gate process with a diffusion barrier layer is provided, comprising providing a semiconductor substrate having a plurality of isolation structures formed thereon. Then, forming a gate oxide layer, a polysilicon layer, a tungsten silicide metal layer in sequence on the semiconductor substrate. Performing an ion implantation with the silicon ions on the semiconductor substrate to form a diffusion barrier layer between the polysilicon layer and the tungsten silicide metal layer. And then, performing a gate lithography process to define a gate structure.

According to another embodiment of the present invention, after defining the gate structure on the semiconductor substrate, an ion implantation with silicon ions is performed on the gate structure to form a diffusion barrier layer between the polysilicon layer and the tungsten silicide layer.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a cross-sectional view of a gate structure according to an embodiment of the present invention;

FIG. 2a through 2d are sectional diagrams illustrating a gate structure of various steps according to a preferred embodiment of the present invention; and

FIGS. 3a through 3c are sectional diagrams illustrating a gate structure of various steps according to another embodiment of the present invention.

### DETAILED DESCRIPTION OF THE PREFERRED EMBODIMENTS

The present invention provides a diffusion barrier layer formed between the polysilicon layer and the tungsten silicide metal layer, which prevents the silicon ion diffusion phenomenon from the chemical potential energy and the stress.

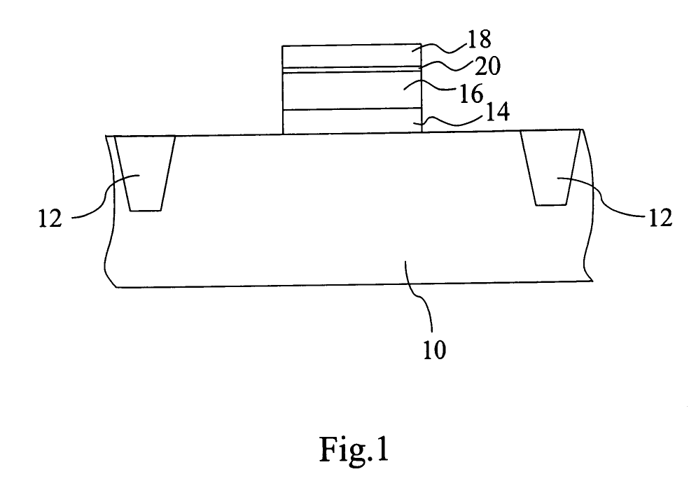

The present invention provides a gate structure having a diffusion barrier layer, as shown in FIG. 1, comprising a semiconductor substrate 10 having a plurality of isolation structures 12 formed therein, and a gate oxide layer 14 on the semiconductor substrate 10. The gate oxide layer 14 is a silicon oxide layer formed by a dry oxidation. A polysilicon layer 16 is formed on the gate oxide layer 14 by using chemical deposition. A tungsten silicide metal layer 18 is formed on the polysilicon layer 16 by using chemical deposition. A diffusion barrier layer 20 is formed between the polysilicon layer 16 and the tungsten silicide metal layer 18 by performing an ion implantation with silicon ions into the semiconductor substrate 10.

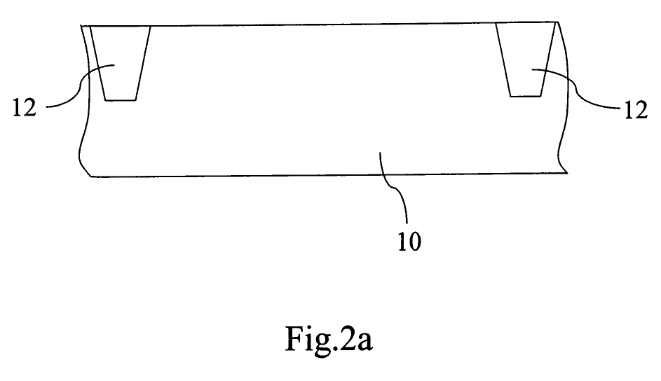

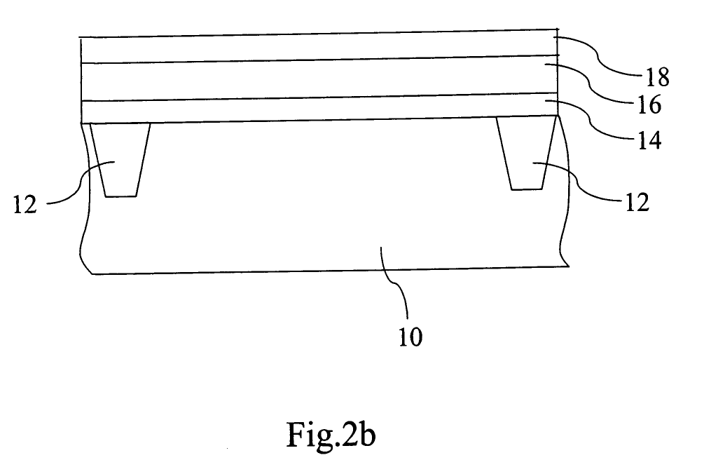

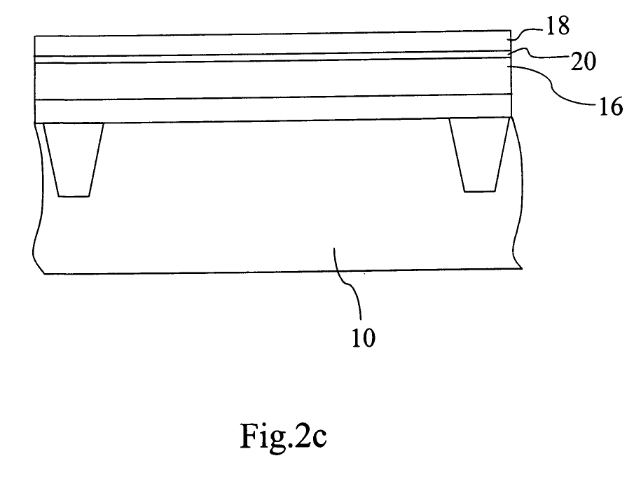

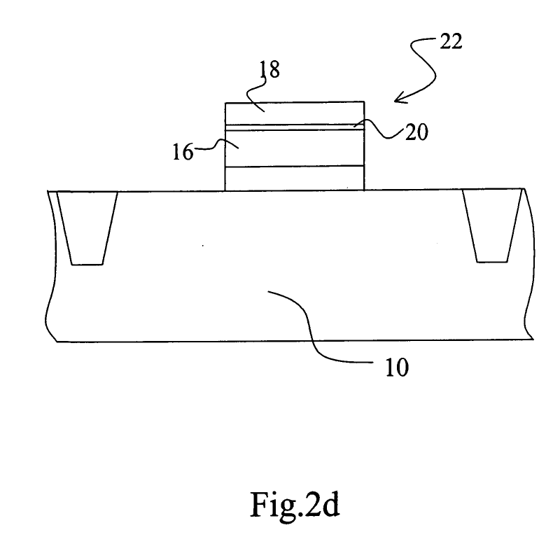

Refer to FIGS. 2a through 2d, which are sectional diagrams illustrating a gate structure having a diffusion barrier layer of various steps according to a preferred embodiment of the present invention. As shown in the drawings, the method of the present invention comprises the following steps.

First, refer to FIG. 2a, a plurality of isolation structures 12 are formed in the semiconductor substrate 10.

Next, a gate structure process is performed. A silicon oxide layer 14 used as a gate oxide layer, a polysilicon layer 16, and a tungsten silicide metal layer 18 in sequence are formed on the semiconductor substrate 10, as shown in FIG. 2b. The silicon oxide layer 14 is made by a dry oxidation in an oxidation furnace. Before performing the dry oxidation, a cleaning process is performed on the semiconductor substrate 10 to maintain the cleanliness of the exposed silicon surface to ensure the quality. The polysilicon layer 16 is formed by chemical deposition, and the resistivity of the polysilicon layer 16 is properly adjusted by a diffusion or an ion implantation. The tungsten silicide metal layer 18 is formed by chemical vapor deposition, and the resistivity of the tungsten silicide metal layer 18 has low resistivity. After this process, an annealing process is performed.

An ion implantation is then performed. The silicon ions are implanted into the tungsten silicide metal layer 18 and the polyslicon layer 16 to form a diffusion barrier layer 20, as shown in the thin film stack structure.

Next, the gate lithography process is performed on the semiconductor substrate 10 to form a gate structure 22 having a diffusion barrier layer 20 as shown in FIG. 2c.

In order to repair the damage caused by the silicon oxide layer 14 from the lithography process, a gate re-oxidation process is usually performed after forming the gate structure 22. In the present invention, due to the temperature effect, the implanted silicon ions with high entropy are induced to move to achieve a stable low entropy, resulting in eliminating the stress variation caused by the polysilicon layer 16 and the tungsten silicide metal layer from the conventional process.

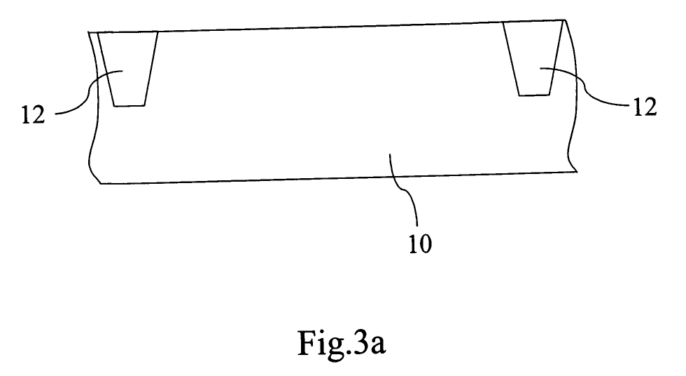

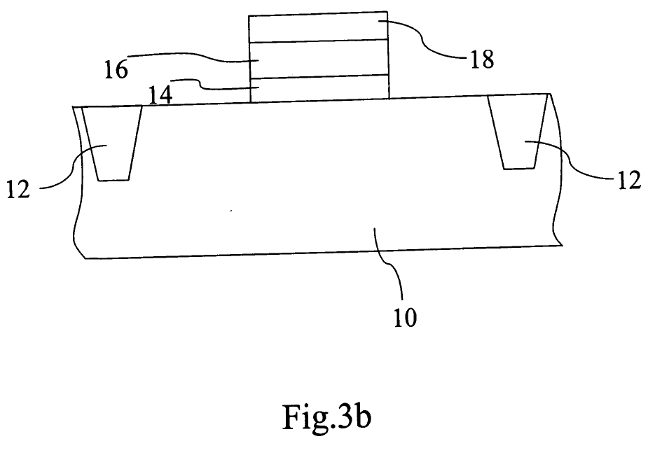

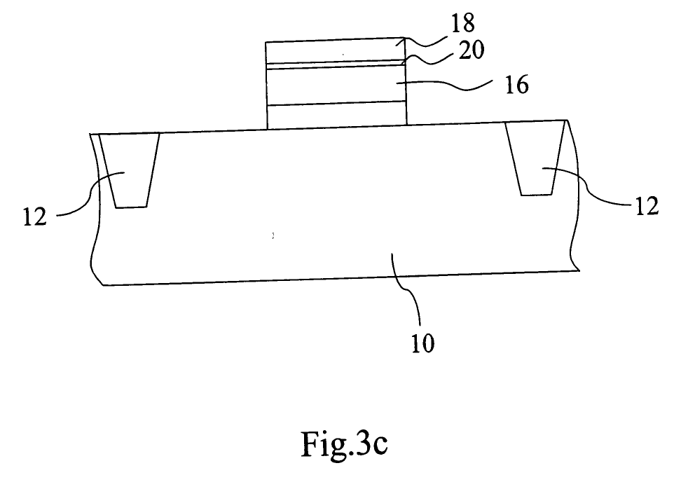

The present invention also provides a fabrication method. A plurality of isolation structures 12 are formed on a semiconductor substrate 10, as shown in the structure of FIG. 3a.

Next, a gate structure process is performed to form a gate structure having a gate oxide 14, a polysilicon layer 16, and a tungsten silicide metal layer 18 on the semiconductor substrate 10, as shown in FIG. 3b.

An ion implantation is performed to implant the silicon ions into the region between the tungsten silicide metal layer 18 and the polysilicon layer 16 to form a diffusion barrier layer 20, as shown in the gate structure of FIG. 3c.

According to the present invention, the present invention provides a gate structure having a diffusion barrier layer and the process for fabrication thereof. A diffusion barrier layer is formed between the metal silicide layer and the polysilicon layer by silicon ion implantation, thereby suppressing the silicon atom diffusion phenomenon caused by the chemical potential energy between the metal silicide and the polysilicon layer. When the gate re-oxidation process is performed by the silicon atom implantation with high energy, the atom movement and the lattice recombination are properly performed to alleviate the stress difference between thin films caused by this process, thereby preventing failure of the gate oxide layer.

The embodiment above is only intended to illustrate the present invention; it does not, however, to limit the present invention to the specific embodiment. Accordingly, various modifications and changes may be made without departing from the spirit and scope of the present invention as described in the following claims.

1. A gate fabrication process with diffusion barrier layer, comprising:
providing a semiconductor substrate having isolation structures formed therein;
forming a gate oxide layer, a polysilicon layer, and a tungsten silicide metal layer in sequence on the semiconductor substrate;
performing an ion implantation on the semiconductor substrate by silicon ions to form a diffusion barrier layer between the polysilicon layer and the tungsten silicide metal layer; and
performing a gate lithography process to define a gate structure.

2. The gate fabrication process with diffusion barrier layer of claim 1, wherein after forming the tungsten silicide metal layer, further performing an annealing process to reduce a resistivity of the tungsten silicide metal layer.

3. The gate fabrication process with diffusion barrier layer of claim 1, wherein the tungsten silicide metal layer is formed by chemical vapor deposition.

4. The gate fabrication process with diffusion barrier layer of claim 1, wherein after defining the gate structure, further performing a re-oxidation process on the gate structure to repair damage caused by the gate oxide layer from the gate lithography process.

5. The gate fabrication process with diffusion barrier layer of claim 1, wherein the polysilicon layer is formed by chemical deposition.

6. The gate fabrication process with diffusion barrier layer on claim 1, wherein a resistivity of the polysilicon layer is reduced by a thermal diffusion or an ion implantation.

7. The gate fabrication process with diffusion barrier layer of claim 1, wherein the material of the gate oxide layer is silicon oxide.

8. The gate fabrication process with diffusion barrier layer of claim 7, wherein silicon oxide is made by dry oxidation in an oxidation furnace.

9. The gate fabrication process with diffusion barrier layer of claim 8, wherein before performing the dry oxidation, further performing a cleaning process on the semiconductor substrate to maintain the cleanliness of the exposed silicon surface.

10. A gate fabrication process with diffusion barrier layer, comprising:
providing a semiconductor substrate having isolation structures formed therein;
forming a gate oxide layer, a polysilicon layer, and a tungsten silicide metal layer in sequence on the semiconductor substrate;
performing a gate lithography process to define a gate structure; and
performing an ion implantation on the semiconductor substrate by silicon ions to form a diffusion barrier layer between the polysilicon layer and the tungsten silicide metal layer.

11. The gate fabrication process with diffusion barrier layer of claim 10, wherein after forming the tungsten silicide metal layer, further performing an annealing process to reduce a resistivity of the tungsten silicide metal layer.

12. The gate fabrication process with diffusion barrier layer of claim 10, wherein the tungsten silicide metal layer is formed by chemical vapor deposition.

13. The gate fabrication process with diffusion barrier layer of claim 10, wherein the polysilicon layer is formed by chemical deposition.

14. The gate fabrication process with diffusion barrier layer of claim 10, wherein a resistivity of the polysilicon layer is reduced by a thermal diffusion or an ion implantation.

15. The gate fabrication process with diffusion barrier layer of claim 10, wherein the material of the gate oxide layer is silicon oxide.

16. The gate fabrication process with diffusion barrier layer of claim 15, wherein silicon oxide is made by dry oxidation in an oxidation furnace.

17. The gate fabrication process with diffusion barrier layer of claim 16, wherein before performing the dry oxidation, further performing a cleaning process on the semiconductor substrate to maintain the cleanliness of the exposed silicon surface.

18. The gate fabrication process with diffusion barrier layer of claim 16, wherein after defining the gate structure, further performing a gate re-oxidation process on the gate structure to repair damage caused by the gate oxide layer by the gate lithograph process.

19-23. (canceled)
